(19) United States
(12) Patent Application Publication
(10) Pub. No.: US 2022/0201853 A1
(43) Pub. Date: Jun. 23, 2022

(54) METHOD FOR MANUFACTUNRING A MULTILAYER CIRCUIT STRUCTURE HAVING EMBEDDED TRACE LAYERS

(71) Applicants: ROHM AND HAAS ELECTRONIC MATERIALS LLC, Marlborough, MA (US); GEBR SCHMID GMBH, Freudenstadt (DE)

(72) Inventors: Chih-Liang Chu, Hsinchu (TW); Yu Cheng Yuan, Hsinchu (TW); Christian Mathias Schmid, Freudenstadt (DE)

(21) Appl. No.: 17/529,764

(22) Filed: Nov. 18, 2021

Related U.S. Application Data
(63) Continuation of application No. 17/232,784, filed on Apr. 16, 2021.
(60) Provisional application No. 63/127,544, filed on Dec. 18, 2020.

(51) Int. Cl. H05K 1/02; H05K 3/00; H05K 9/00

(52) U.S. Cl. CPC H05K 1/0298; H05K 2203/0353; H05K 9/0073; H05K 3/0041

(57) ABSTRACT

Provided herein are methods for manufacturing a multilayer circuit structure having embedded circuits and the multilayer circuit structure made thereby. A substrate having at least one existing circuit on the surface is provided, then a dielectric layer is formed to cover the existing circuit. A metal layer is subsequently formed on the dielectric layer. The metal layer is made into a metal mask with a pattern by photoimaging, then the pattern is transferred to the dielectric layer underneath by plasma etching to create multiple trenches and pads at the same time. After vias are made at the pads, a conductive metal is deposited into the trenches and vias to form an embedded trace layer with excess conductive metal in the dielectric layer. The excess conductive metal is removed to obtain a new circuit embedded in the dielectric layer and is coplanar with the surface of the dielectric layer.

The present application is a continuation-in-part application which claims the benefit of parent application Ser. No. 17/232,784 filed in the U.S. Patent Office on Apr. 16, 2021 which claims the benefit of provisional patent application Ser. No. 63/127,544 filed in the U.S. Patent Office on Dec. 18, 2020.

### TECHNICAL FIELD

The invention relates to the field of integrated circuits and packaging, and to a method for manufacturing a multilayer circuit structure, and the structure made thereby.

### BACKGROUND

As the trend of the consumer electronic and communication products is toward lighter, thinner, and higher efficiency, the circuit substrate used on a main board of the electronic products requires to have higher layout density. In the electronics products, the circuit substrate, e.g., a printed circuit board (PCB) for packaging integrated circuits (IC or chips) also plays an important role. As the contact number and the contact density of a chip increase, the contact number and the contact density of a circuit substrate for packaging chips increase correspondingly. Therefore, the requirement of circuit substrates with higher layout density is a continuous need.

Currently, the method for stacking a plurality of patterned conductive layers and a plurality of dielectric layers on a circuit substrate includes a laminating process and a build-up process. These processes include laminating the dielectric layers on the surface of patterned conductive layers; then a plated through hole (PTH) or a via serves as the channel for connecting the patterned conductive layers residing on the different dielectric layers.

U.S. Pat. No. 9,237,643 B2 discloses a conventional fabrication process for a circuit board having an embedded circuit on one side. The fabrication process includes: i) providing a core panel having dielectric layers on both outer surfaces, ii) forming fine circuit grooves (i.e., trenches) and at least one through hole or via by laser ablating on one outer surface; iii) filling the fine circuit grooves and through hole and/or via with conductive material by electroplating; iv) removing the excess conductive material, for example, by grinding to form an embedded fine circuit on one surface of the core panel. The other surface of the core panel now covered with un-patterned conductive layer may be further processed to form patterned conductive layer by a subtractive process, an additive process, or a semi-additive process. Finally, a patterned solder mask may be formed on each outer surface to complete the fabrication of a circuit board.

U.S. Pat. No. 8,164,004 B2 discloses a similar fabrication process for a circuit board having embedded circuits 11a and 11b on both sides of a core panel 10 (see FIG. 1). The fabrication process includes: i) forming a through hole 12 in the core panel, ii) forming two indent patterns respectively on two opposite surfaces of the core panel by laser ablating, iii) filling the through hole and the indent patterns with a conductive material by electroplating, iv) planarizing the circuit to be level with the two surfaces of the core panel respectively by etching or polishing to obtain the embedded circuits 11a and 11b.

According to the aforesaid fabrication processes, the circuit pattern is formed in the dielectric material by laser ablating on one or both surfaces of a core panel. One of the drawbacks of the laser ablation process is that the process is slow, thus low through-put and leads into increased production cost. Another concern is that the circuits 11a and 11b formed by laser ablating has a trench profile of a trapezoid with slanted sidewalls versus a desired rectangular with vertical sidewalls (see FIG. 1). The resulting circuit having slanted sidewalls is expected to increase signal loss for signal transmission at high speed and high frequency. Consequently, it is highly sought after by the circuit board fabricators to have new methods for manufacturing substrates with embedded circuit structures that have high through-put and provide substrates suitable for the high speed and high frequency applications.

### SUMMARY OF THE INVENTION

The present invention is directed to a method for manufacturing a multilayer circuit structure having embedded trace layers and the multilayer circuit structure made thereby.

According to the first aspect of the present invention is to provide a method for manufacturing a multilayer circuit structure, comprising:
(i) providing a substrate having at least one layer of an existing conductor, where the substrate is a single-side PCB, a double-side PCB, or a package substrate;
(ii) forming a dielectric layer covering the existing conductor;
(iii) forming a metal layer on the dielectric layer;
(iv) patterning the metal layer by photoimaging to form a metal mask;
(v) plasma etching the dielectric layer to form an indent pattern composed of multiple trenches and pads on the surface of the dielectric layer at areas not shielded by the metal mask;
(vi) optionally, removing the metal mask by chemical etching or plasma etching;
(vii) forming at least one via at a pad by laser drilling or plasma etching to expose a portion of the existing conductor underneath;
(viii) depositing a conductive metal completely filling the patterned dielectric layer to form an embedded trace layer with excess conductive metal; and
(ix) planarizing to remove the excess conductive metal of step (viii) to form a new circuit embedded in the dielectric layer of the substrate;

wherein
when the substrate is a double-side PCB, then steps (ii)-(ix) are applicable to the existing conductors located on both side of the substrate, the double-side PCB has at least one through hole, and the through hole is filled with a metallic material composed of Cu or Cu alloy or an organic polymer composed of epoxy resin or phenolic resin.

In an embodiment, the method of the present invention, wherein the step (iv) patterning the metal layer by photoimaging, comprises:
(a) coating or laminating a layer of photoresist on the metal layer,
(b) patterning the photoresist,
(c) etching the metal layer in the exposed areas by plasma etching or chemical etching, and
(d) removing the remained photoresist pattern by stripping or etching to obtain a metal mask.

According to the second aspect of the present invention is to provide a multilayer circuit structure manufactured by the present method, comprising:
a substrate having at least one layer of an existing conductor, where the substrate is a single-side PCB, a double-side PCB, or a package substrate; and
a dielectric layer having an embedded new circuit formed on top of the substrate's existing conductor;

wherein
the substrate is a single-side print circuit board that has a thickness ranging from about 40 μm to about 800 μm;
the substrate is a double-side print circuit board having at least one through hole, the through hole is filled with a metallic material composed of Cu or Cu alloy or an organic polymer, and the double-side print circuit board has a thickness ranging from about 40 μm to about 800 μm; or the substrate is a package substrate loaded with at least one chip and a plurality of exposed copper pillars, and the package substrate has a thickness ranging from about 100 μm to about 300 μm;
the dielectric layer has a thickness ranging from about 10 μm to about 80 μm;
the new circuit consists a plurality of metal traces and conductive vias, where each metal trace has a width ranging from about 5 μm to about 2500 mm and an embedded depth ranging from about 5 μm to about 50 μm, and each conductive via has a diameter ranging from about 20 μm to about 250 μm and an embedded depth allowing connection with the existing conductor.

Various other features, aspects, and advantages of the present invention will become more apparent with reference to the following Figures, description, examples, and appended claims. The following figures are included for better understanding of the invention and are incorporated in and constitute a part of this specification.

### BRIEF DESCRIPTION OF THE DRAWINGS

FIG. 1 illustrates a circuit board with embedded circuits on both surfaces of a core panel that is manufactured by a conventional fabrication process with a trapezoid trench profile.

FIG. 2A illustrates a first embodiment of the present invention showing a substrate with a dielectric core layer and an existing circuit.

FIG. 2B illustrates a first embodiment of the present invention showing a dielectric layer formed by coating a thermally curable polymer on the existing circuit.

FIG. 2C illustrates a first embodiment of the present invention showing a metal layer deposited on top the dielectric layer.

FIG. 2D illustrates a first embodiment of the present invention showing the metal layer being patterned by photoimaging to form a metal mask.

FIG. 2E illustrates a first embodiment of the present invention showing the dielectric layer being patterned by plasma etching at areas not shielded by the metal mask.

FIG. 2F illustrates a first embodiment of the present invention showing a via formed by a laser drilling at a pad to expose a portion of the existing conductor.

FIG. 2G illustrates a first embodiment of the present invention showing a conductive metal deposited to fill the patterned dielectric layer, trenches and via to form a trace layer with excess conductive metal.

FIG. 2H illustrates a first embodiment of the present invention where excess conductive metal of the trace layer is removed.

FIG. 2I illustrates a first embodiment of the present invention showing a 3-layer circuit structure with two embedded circuit in dielectric layers.

FIG. 3A illustrates a second embodiment of the present invention showing a double-sided substrate containing a dielectric core layer and two existing circuits residing on opposite surfaces of the dielectric core layer and a through-hole.

FIG. 3B illustrates a second embodiment of the present invention showing dielectric layers formed by coating thermally curable polymers on the existing circuits.

FIG. 3C illustrates a second embodiment of the present invention showing metal layers formed on the dielectric layers.

FIG. 3D illustrates a second embodiment of the present invention showing metal layers patterned by photoimaging to form a metal mask.

FIG. 3E illustrates a second embodiment of the present invention showing the dielectric layers patterned by plasma etching at areas not shielded by the metal mask.

FIG. 3F illustrates a second embodiment of the present invention showing removal of the metal masks to expose the dielectric layers with indent patterns.

FIG. 3G illustrates a second embodiment of the present invention showing multiple via formed by laser drilling to expose existing circuits.

FIG. 3H illustrates a second embodiment of the present invention showing conductive metal deposited to fill the indent pattern forming trace layers with excess conductive metal.

FIG. 3I illustrates a second embodiment of the present invention showing the excess conductive metal of the trace layers removed.

FIG. 4A illustrates a third embodiment of the invention showing a double-sided substrate with a dielectric core layer and two existing circuits and a through-hole being filled with metallic material.

FIG. 4B illustrates a third embodiment of the present invention showing the dielectric layers and the metal layers formed by laminating a single-side metal clad with the dielectric layers.

FIG. 4C illustrates a third embodiment of the present invention showing the metal layers patterned by photoimaging to form metal masks.

FIG. 4D illustrates a third embodiment of the present invention showing the dielectric layers patterned by plasma etching at areas not shielded by the metal masks to form indent patterns.

FIG. 4E illustrates a third embodiment of the present invention where the metal masks are removed to expose dielectric layers with the indent patterns.

FIG. 4F illustrates a third embodiment of the present invention showing multiple via exposing a portion of the existing circuits.

FIG. 4G illustrates a third embodiment of the present invention showing conductive metal deposited to fill the indent patterns to form trace layers with excess metal.

FIG. 4H illustrates a third embodiment of the present invention showing excess conductive metal of the trace layers removed.

FIG. 5A illustrates a fourth embodiment of the present invention shows a package substrate containing a chip with a plurality of copper pillars enclosed in a dielectric core layer.

FIG. 5B illustrates a fourth embodiment of the present invention where a dielectric layer is formed on the dielectric core layer.

FIG. 5C illustrates a fourth embodiment of the present invention showing a metal layer deposited on the dielectric layer.

FIG. 5D illustrates a fourth embodiment of the present invention showing the metal layer patterned by photoimaging to form a metal mask.

FIG. 5E illustrates a fourth embodiment of the present invention showing the dielectric layer patterned at areas not shielded by the metal mask to form an indent pattern.

FIG. 5F illustrates a fourth embodiment of the present invention showing the metal mask removed.

FIG. 5G illustrates a fourth embodiment of the present invention showing a via formed by laser drilling to expose a portion of the copper pillars of the chip.

FIG. 5H illustrates a fourth embodiment of the present invention showing a conductive material deposited to fill the indent pattern and via to form the trace layer with excess conductive metal.

FIG. 5I illustrates a fourth embodiment of the present invention showing the excess conductive material of the trace layer removed.

FIG. 6A illustrates a fifth embodiment of the present invention showing a substrate containing a dielectric core layer, two dielectric layers on opposite sides of the dielectric core layer and two existing circuits connected by a through-hole filled with an organic polymer.

FIG. 6B illustrates a fifth embodiment of the present invention showing a conductive metal deposited to form trace layers and trenches and via at least partially filled with the conductive metal.

FIG. 6C illustrates a fifth embodiment of the present invention showing the substrate subjected to lithography to form patterned resist layers.

FIG. 6D illustrates a fifth embodiment of the present invention showing conductive metal completely filling partially filled metal traces and via.

FIG. 6E illustrates a fifth embodiment of the present invention shows the patterned resist layers removed to expose trace layers and trenches and via filled with conductive metal.

FIG. 6F illustrates a fifth embodiment of the present invention excess portion of trance layers removed and a substrate with a four layer circuit structure with trace layers and embedded dielectric layers.

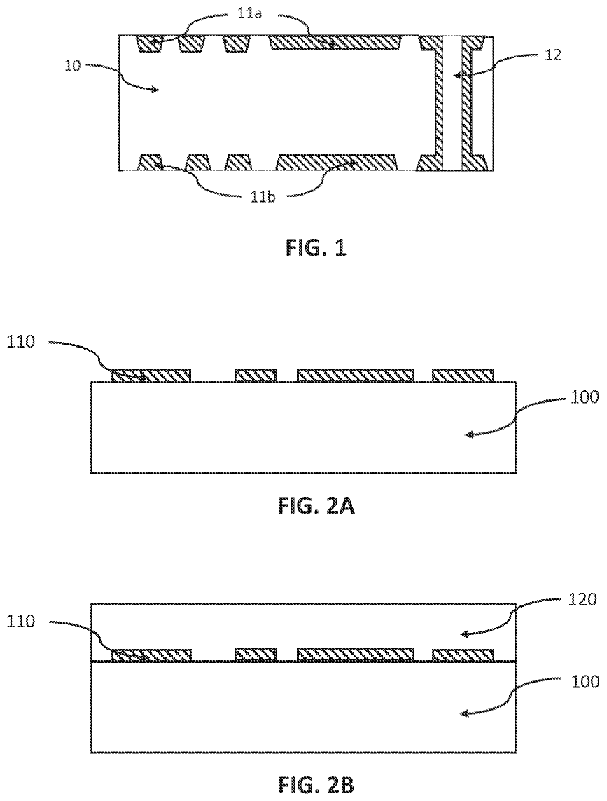

### DETAILS OF THE INVENTION

All publications, patent applications, patents and other references mentioned herein, if not otherwise indicated, are explicitly incorporated by reference herein in their entirety for all purposes as if fully set forth.

Unless otherwise defined, all technical and scientific terms used herein have the same meaning as commonly understood by one of ordinary skill in the art to which this invention belongs. In case of conflict, the present specification, including definitions, will control.

Unless stated otherwise, all percentages, parts, ratios, etc., are by weight.

As used herein, the term “produced from” is synonymous to “comprising”. As used herein, the terms “comprises,” “comprising,” “includes,” “including,” “has,” “having,” “contains” or “containing,” or any other variation thereof, are intended to cover a non-exclusive inclusion. For example, a composition, process, method, article, or apparatus that comprises a list of elements is not necessarily limited to only those elements but may include other elements not expressly listed or inherent to such composition, process, method, article, or apparatus.

The transitional phrase “consisting of” excludes any element, step, or ingredient not specified. If in the claim, such a phrase would close the claim to the inclusion of materials other than those recited except for impurities ordinarily associated therewith. When the phrase “consisting of” appears in a clause of the body of a claim, rather than immediately following the preamble, it limits only the element set forth in that clause; other elements are not excluded from the claim as a whole.

The transitional phrase “consisting essentially of” is used to define a composition, method or apparatus that includes materials, steps, features, components, or elements, in addition to those literally discussed, provided that these additional materials, steps features, components, or elements do not materially affect the basic and novel characteristic(s) of the claimed invention. The term “consisting essentially of” occupies a middle ground between “comprising” and “consisting of”.

The term “comprising” is intended to include embodiments encompassed by the terms “consisting essentially of” and “consisting of”. Similarly, the term “consisting essentially of” is intended to include embodiments encompassed by the term “consisting of”.

When an amount, concentration, or other value or parameter is given as either a range, preferred range or a list of upper preferable values and lower preferable values, this is to be understood as specifically disclosing all ranges formed from any pair of any upper range limit or preferred value and any lower range limit or preferred value, regardless of whether ranges are separately disclosed. For example, when a range of “1 to 5” is recited, the recited range should be construed as including ranges “1 to 4”, “1 to 3”, “1-2”, “1-2 & 4-5”, “1-3 & 5”, and the like. Where a range of numerical values is recited herein, unless otherwise stated, the range is intended to include the endpoints thereof, and all integers and fractions within the range.

When the term “about” is used in describing a value or an end-point of a range, the disclosure should be understood to include the specific value or end-point referred to.

Further, unless expressly stated to the contrary, “or” refers to an inclusive “or” and not to an exclusive “or”. For example, a condition A “or” B is satisfied by any one of the following: A is true (or present) and B is false (or not present), A is false (or not present) and B is true (or present), and both A and B are true (or present).

As used herein, the term “trace layer” is used interchangeably with the term “circuit.” Analogously, the term “embedded trace layer” and the term “embedded circuit” are used interchangeably herein.

Embodiments of the present invention as described in the Summary of the Invention include any other embodiments described herein, can be combined in any manner.

The invention is described in detail herein under.

### First Embodiment

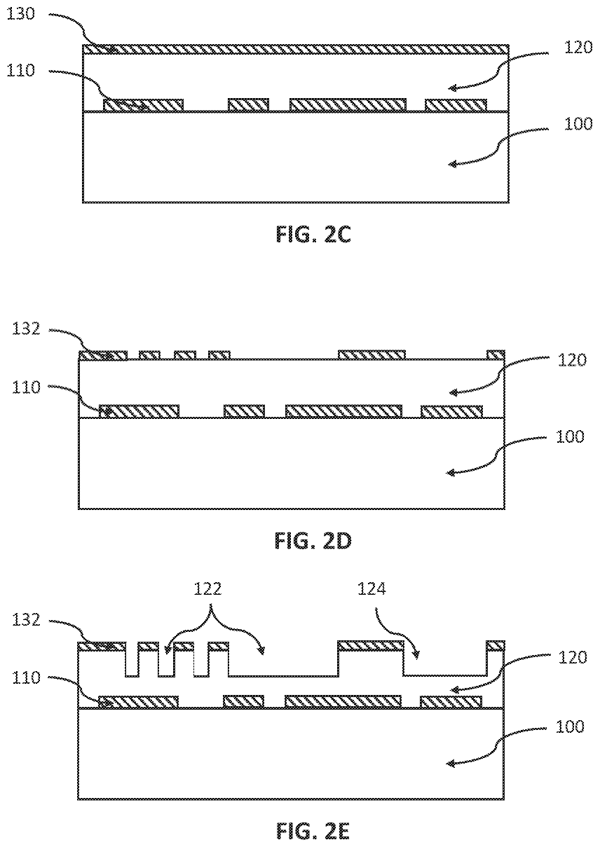

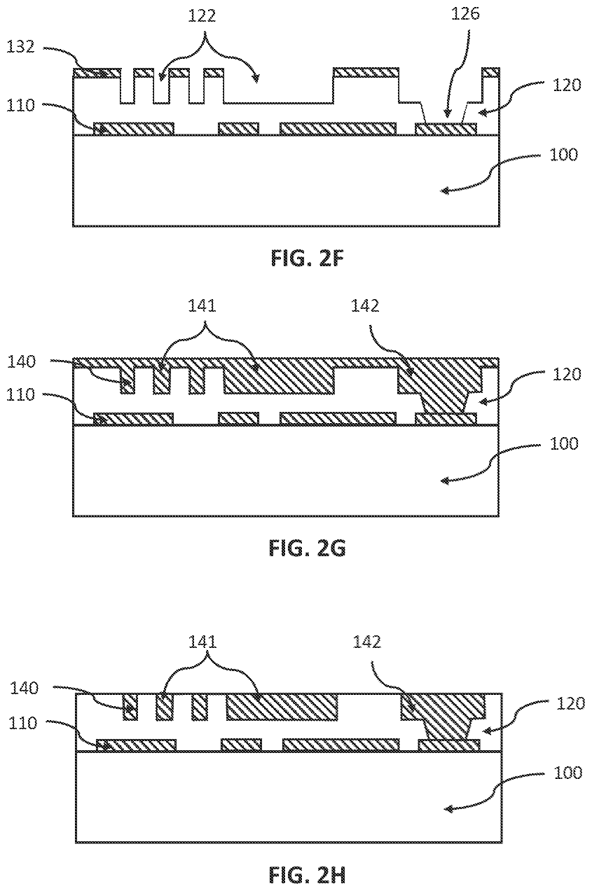

In the first embodiment of the present invention, a method for manufacturing a multilayer circuit structure on a single-side PCB is described. FIGS. 2A-2I are profile flowcharts illustrating the steps according to a first embodiment of the present invention.

Referring to FIG. 2A, according to step (i) of the present method, a single-side PCB is provided as a substrate. The substrate contains a dielectric core layer 100 and an existing circuit 110 on the surface of the dielectric core layer.

In one embodiment, the substrate has a thickness ranging from about 40 μm to about 800 μm, and is derived from a copper clad laminate that has a base sheet composed of a reinforced resin or a resin coated copper (RCC) foil, and the resin is selected from epoxy resin, phenolic resin, bismaleimide-triazine resin (BT), polyimide (PI), cyanate ester resin (CE), poly-phenylene oxide (PPE), liquid crystal polymer (LCP), polytetrafluoroethylene (PTFE), and mixtures thereof.

Referring to FIG. 2B, according to step (ii) of the present method, a dielectric layer 120 is formed by coating a thermally curable polymer on the existing circuit 110. The dielectric layer of step (ii) generally has a thickness ranging from about 10 μm to about 80 μm.

In one embodiment, the thermally curable polymer is selected from the group consisting of epoxy resin, bismaleimide-triazine resin (BT), polyimide (PI), cyanate ester resin (CE), polyphenylene oxide (PPE), liquid crystal polymer (LCP), polytetrafluoroethylene (PTFE), and mixtures thereof.

In another embodiment, the dielectric layer further comprises a reinforcing material or a plurality of fillers.

In yet another embodiment, the reinforcing material is in form of fibers or a fabric, and comprises E-glass, S-glass, quartz, ceramic, or aramid.

In a further embodiment, the plurality of fillers are particles composed of silicon oxide, aluminum oxide, boron nitride, and mixtures thereof, and the filler particles have an average diameter ranging from about 1 μm to about 20 μm.

Referring to FIG. 2C, according to step (iii) of the present method, a metal layer 130 is deposited on top of the dielectric layer 120. The metal layer generally has a thickness ranging from about 0.1 μm to about 15 μm.

In one embodiment, the metal layer is formed by physical vapor deposition (PVD), chemical vapor deposition (CVD), or electroless-plating. Noted that in the PCB fabrication industry the PVD method is also referred as “sputtering.” In one embodiment, the metal layer is composed of Cu, Ni, Ti, W, Al, Cr, Co, Ag, Au, Pd, and alloy thereof. In another embodiment, the metal layer is composed of Cu and Cu alloy.

Referring to FIG. 2D, according to step (iv) of the present method, the metal layer 130 is patterned by photoimaging to form a metal mask 132 on the surface of the dielectric layer 120. The photoimaging process used to form the metal mask 132 is described in detail below.

According to the present method, the photoimaging process comprises:
(a) coating or laminating a layer of photoresist on the metal layer,
(b) patterning the photoresist,
(c) etching the metal layer in the exposed areas by plasma etching or chemical etching; and
(d) removing the remained photoresist pattern by stripping or etching to obtain a metal mask.

Referring to FIG. 2E, according to step (v) of the present method, the dielectric layer 120 is then patterned by plasma etching at areas not shielded by the metal mask 132 to form an indent pattern including multiple trenches 122 and pads 124 on the surface of the dielectric layer. Noted that the trenches and pads produced by plasma etching will have vertical sidewalls, also referred as a rectangular profile.

Noted that the metal mask may be removed before or after the via formation step (vii). Alternatively, provided that the metallic material of the metal mask is the same as the conductive metal is used in the step (viii), it may not be removed at all.

Referring to FIG. 2F, according to step (vii) of the present method, at least one via 126 may be formed by laser drilling at the pad 124 to expose a portion of the existing conductor underneath, i.e., the existing circuit 110. As shown, the via 126 made by laser drilling has a trapezoid profile.

Depending on the application of the multilayer circuit structure, the step (vii) of forming at least one via may be done by plasma etching to provide a via profile with vertical sidewalls to minimize the signal loss.

Referring to FIG. 2G, according to step (viii) of the present method, a conductive metal is deposited to completely fill the patterned dielectric layer 120 including the trenches 122 and the via 126 to form the trace layer 140 with excess conductive metal. Preferably, the deposited conductive metal is the same as the conductive material used to form the metal mask 132. As the conductive metal has also filled the via, the conductive via 142 serves as a connecting channel between the newly formed trace layer 140 and the existing circuit 110.

The method for depositing the conductive metal may include pre-forming a seed layer and followed by electrolytic plating. Suitable method for forming the seed layer includes, but not limited to, physical vapor deposition (PVD), chemical vapor deposition (CVD), or electroless plating.

When trace pattern of the dielectric layer contains trenches and vias with a broad range of widths and diameters, to obtain a trace layer 140 with uniform thickness becomes a challenge by a single plating process. Especially, when multiple trenches (including the ground area) and vias of the trace pattern have a width and diameter being greater than 150 μm.

One aspect of the invention is to provide a dual plating method to solve the abovementioned problem.

In one embodiment, the electrolytic plating includes a single plating method or a dual plating method.

The dual plating method of the present invention may comprise steps I-IV as follows:
I. forming a patterned resist layer to mask the trenches and vias having a trench width and a via diameter of 150 μm or less;
II. electrolytic plating the first time to deposit conductive metal to the unmasked trenches and vias having a trench width and a via diameter greater than 150 μm to fill up to about 50˜90% of the depth of the trenches and vias;
III. removing the patterned resist layer to expose the trenches and vias having a trench width and a via diameter of 150 μm or less; and
IV. electrolytic plating the second time to ensure all the trenches and vias have been 100% filled with the conductive metal.

Alternatively, the dual plating method of the present invention may comprise steps A-D as follows:
A. electrolytic plating the first time to deposit conductive metal to completely fill the depth of each trench and via having a trench width and a via diameter of 150 μm or less;
B. forming a patterned resist layer to mask the trenches and vias having been completely filled with the conductive metal in Step A;
C. electrolytic plating the second time to ensure all the unmasked trenches and vias having a trench width and a via diameter greater than 150 μm to be filled at least to 100% of the depth of the trenches and vias; and
D. removing the patterned resist layer to expose the trenches and vias having completely filled with the conductive metal in Step A.

Referring to FIG. 2H, according to step (ix) of the present method, the excess conductive metal of the trace layer 140 is removed so that the surfaces of the metal traces 141 and the conductive via 142 are coplanar with the surface of the dielectric layer 120 to form the new circuits. The step is also referred as “planarization.” The resulting substrate is a 2-layer circuit structure with a new circuit, i.e., the trace layer 140 embedded in the dielectric layer 120. The new circuit, excluding the vias, has an embedded depth ranging from about 5 μm to about 50 μm.

In one embodiment, the planarization method includes etching, mechanical grinding, or chemical mechanical polishing (CMP).

In another embodiment, the planarization method includes electrolytic thinning, flash etching, surface ablation/plasma cleaning, or other related techniques.

Referring to FIG. 2I, according to the present method, the 2-layer circuit structure is subjected to the steps (ii)-(ix) as shown in FIG. 2B-2H to provide a 3-layer circuit structure having two embedded circuits 170 and 140 within the respective dielectric layers 150 and 120.

Noted that steps (ii)-(ix) of the present method may be repeated multiple times as needed to provide a multilayer circuit structure.

### Second Embodiment

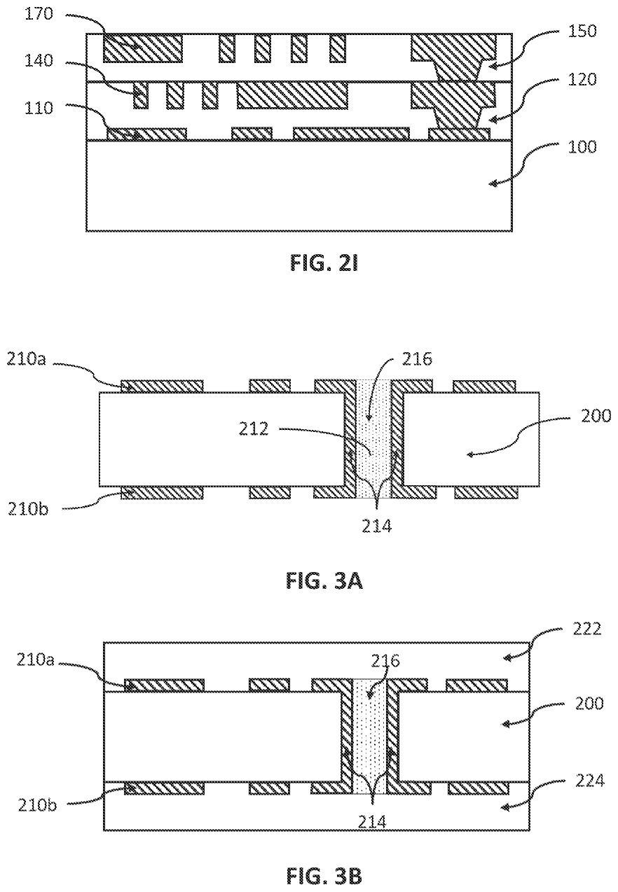

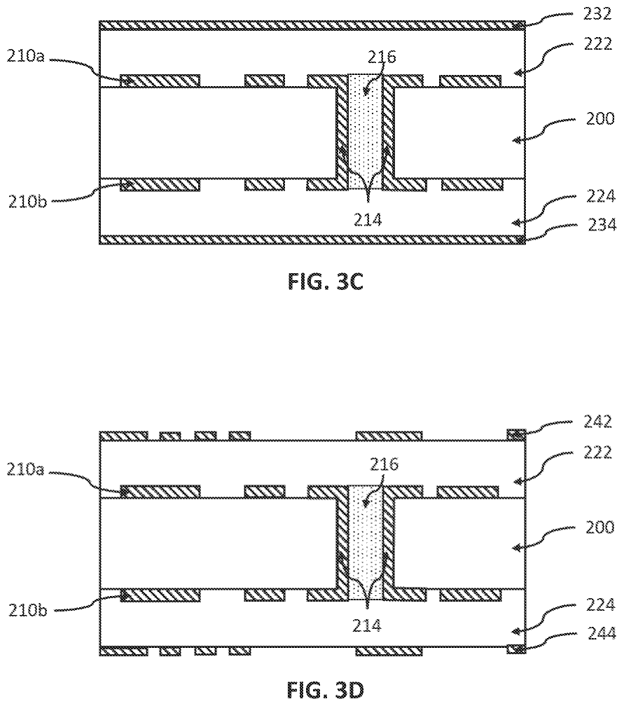

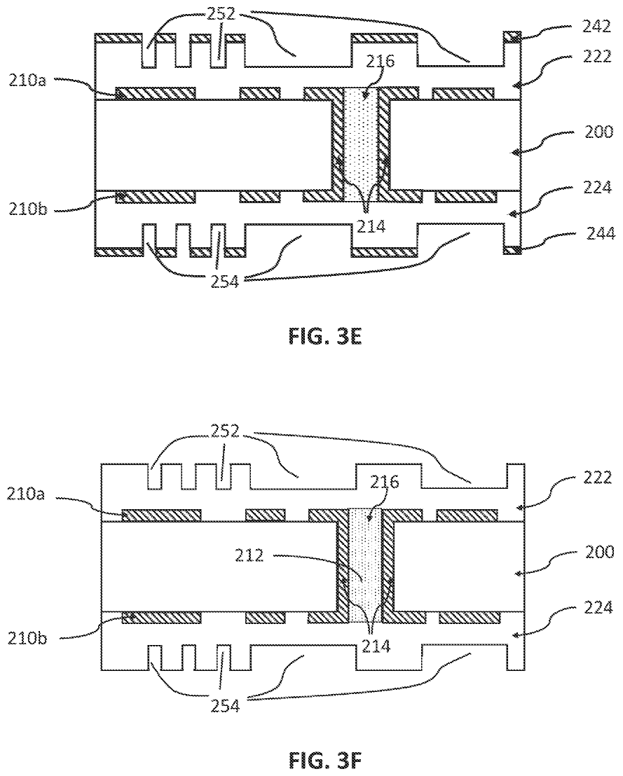

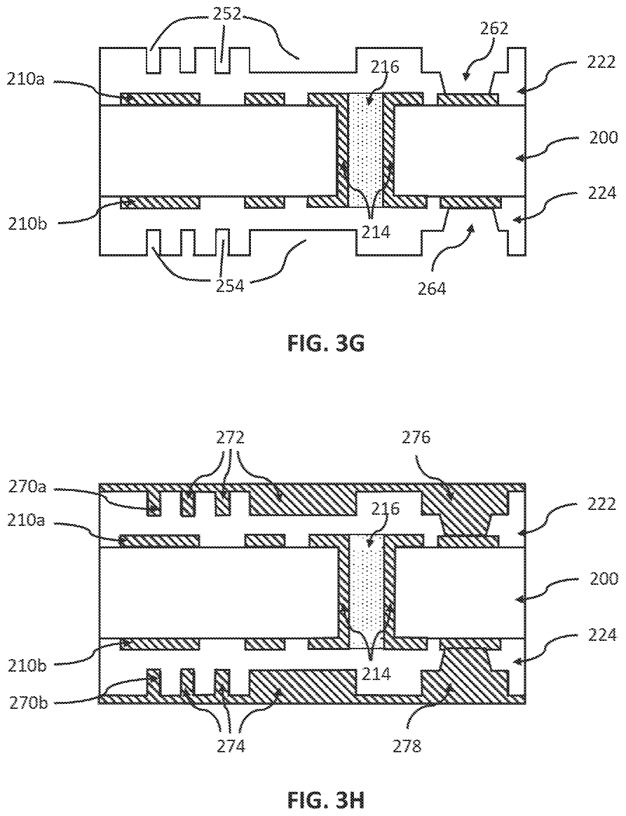

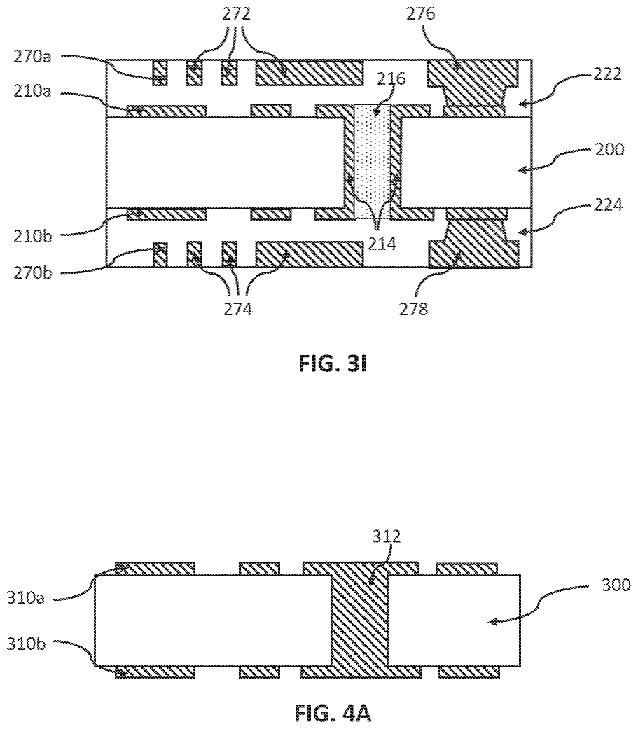

In the second embodiment of the present invention, a method for manufacturing a multilayer circuit structure on a double-side PCB is described. FIGS. 3A-3I are profile flowcharts illustrating the steps according to a first embodiment of the present invention.

Referring to FIG. 3A, according to step (i) of the present method, a double-side PCB is provided as a substrate. The substrate contains a dielectric core layer 200, two existing circuits 210a and 210b residing on the opposite surfaces of the dielectric core layer, and a through hole 212 being a hollow cylinder with an average diameter of about 50 μm to about 250 μm. The through hole is coated with a layer of metallic material 214 which connects the existing circuits 210a and 210b. The through hole is filled with an organic polymer 216 composed of epoxy resin, phenolic resin, or the like before subjecting to the next step.

In one embodiment, the through hole is a hollow cylinder with a layer of metallic material composed of Cu or Cu alloy with a layer thickness of about 15 μm to about 25 μm.

In another embodiment, the through hole first coated with a layer of metallic material is then filled with an organic polymer composed of epoxy resin or phenolic resin.

Referring to FIG. 3B, according to step (ii) of the present method, the dielectric layers 222 and 224 are formed by coating a thermally curable polymer or laminating a prepreg composed of thermally curable polymer on the existing circuits 210a and 210b, respectively.

Noted that since the through hole 212 has been filled with an organic polymer 216, the thermally curable polymers for forming the dielectric layers 222 and 224 may be the same or different.

In one embodiment, the thermally curable polymers for forming the dielectric layers 222 and 224 are the same.

Referring to FIG. 3C, according to step (iii) of the present method, the metal layers 232 and 234 are formed respectively on the dielectric layers 222 and 224 by depositing a conductive metal or by laminating a metal foil.

Referring to FIG. 3D, according to step (iv) of the present method, the metal layers are patterned by photoimaging to form the metal masks 242 and 244 on the respective surface.

Referring to FIG. 3E, according to step (v) of the present method, the dielectric layers 222 and 224 are patterned by plasma etching at areas not shielded by the metal masks 242 and 244 to form indent patterns 252 and 254 on the surface of the respective dielectric layer 222 and 224.

Referring to FIG. 3F, according to step (vi) of the present method, the metal masks 242 and 244 are removed by chemical etching or plasma etching to expose the dielectric layers with the indent patterns 252 and 254.

Referring to FIG. 3G, according to step (vii) of the present method, multiple vias, exemplified by 262 and 264, are formed by laser drilling to expose a portion of the existing conductors underneath, i.e., the existing circuits 210a and 210b.

Referring to FIG. 3H, according to step (viii) of the present method, a conductive metal is deposited to completely fill the respective indent pattern 252 or 254 to form the trace layer 270a or 270b with excess conductive metal, respectively. As the conductive material has also filled the via, the conductive via 276 (or 278) serve as the connecting channels between the newly formed trace layer 270a (or 270b) and the existing circuit 210a (or 210b).

Referring to FIG. 3I, according to step (ix) of the present method, the excess conductive metal of the trace layer 270a or 270b is then removed so that the surfaces of the metal traces (272 and 274) and the multiple conductive vias (276 and 278) on each side are coplanar with the surface of the respective dielectric layer 222 or 224 to form the new circuit, i.e., the trace layer 270a or 270b. The resulting substrate is a 4-layer circuit structure with new circuits, i.e., the trace layers 270a and 270b embedded in the respective dielectric layers 222 and 224.

As described previously, suitable planarization method includes etching, mechanical grinding, or chemical mechanical polishing.

### Third Embodiment

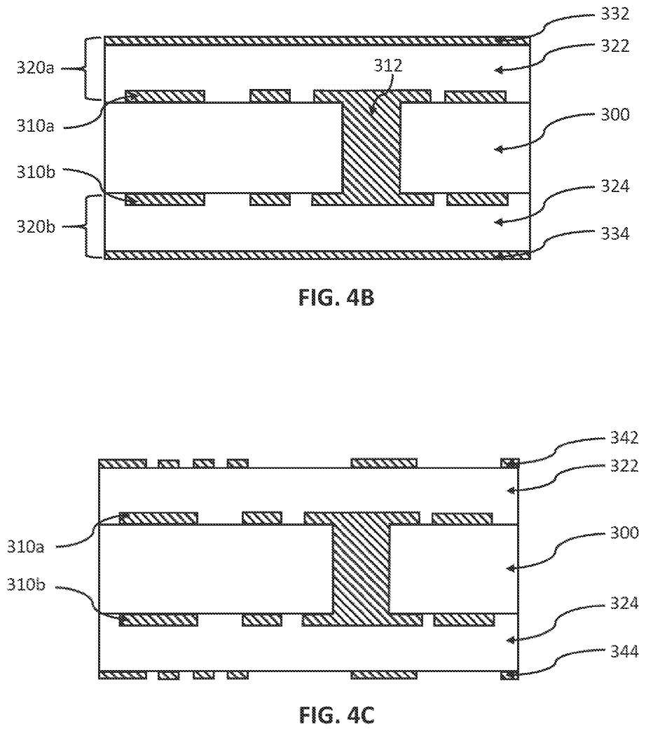

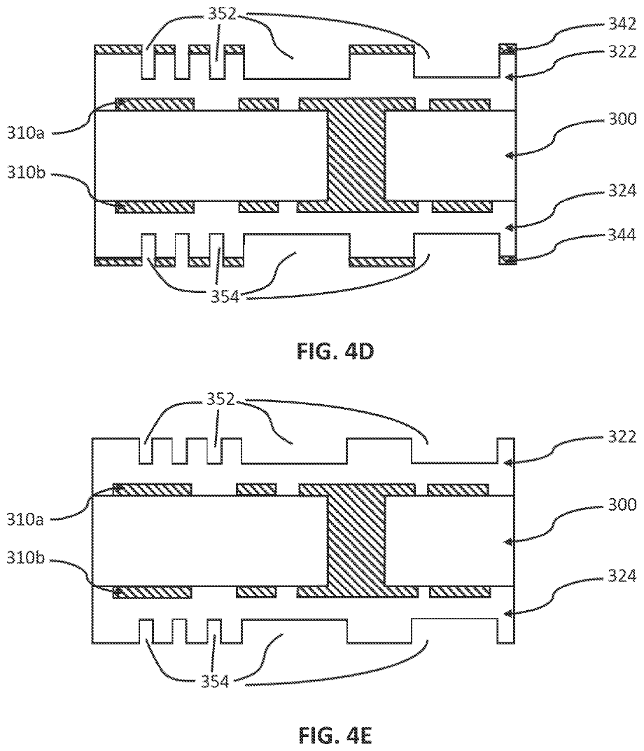

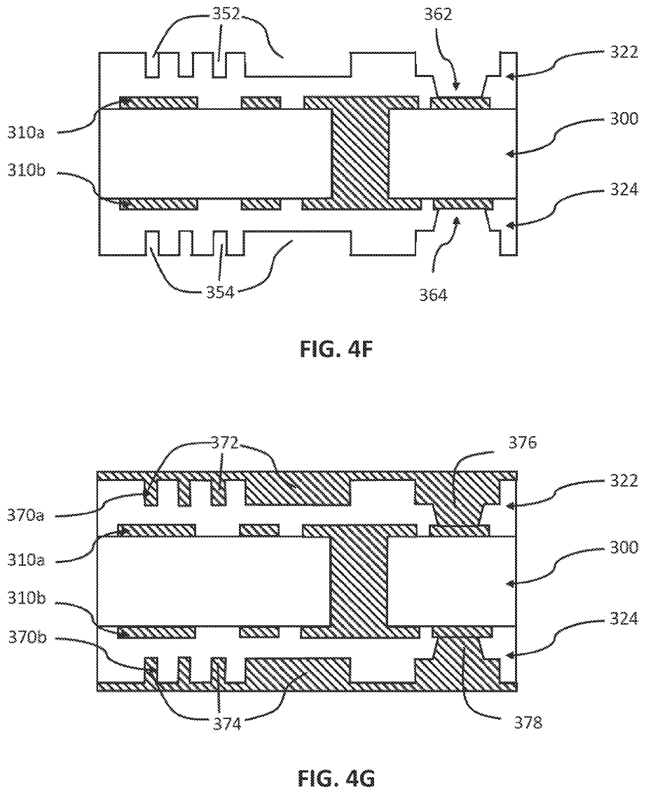

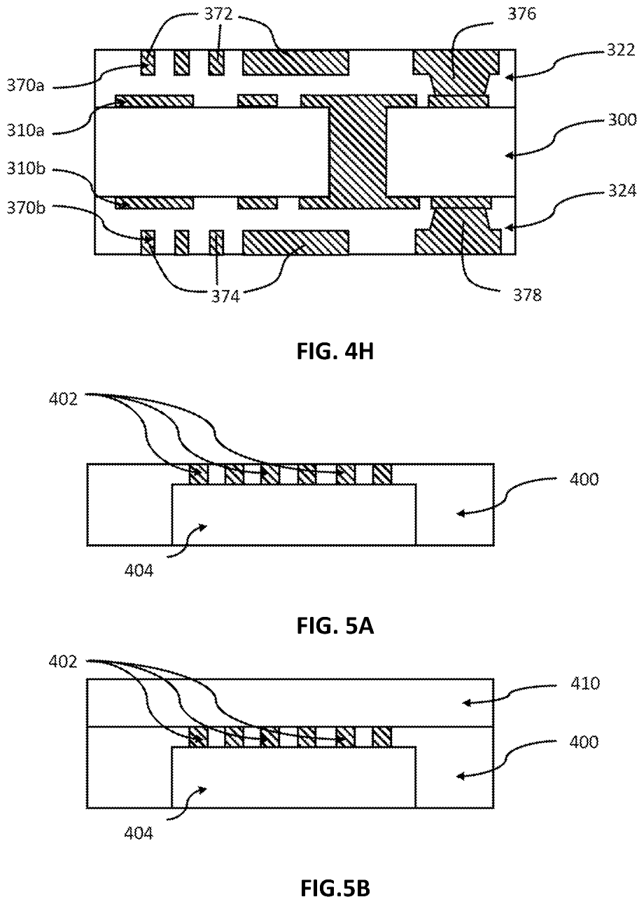

In the third embodiment of the present invention, a method for manufacturing a multilayer circuit structure on a double-side PCB is described. FIGS. 4A-4H are profile flowcharts illustrating the present method according to a third embodiment of the present invention.

Referring to FIG. 4A, according to step (i) of the present method, a double-side PCB is provided as a substrate. The substrate contains a dielectric core layer 300, two existing circuits 310a and 310b residing on the opposite surfaces of the dielectric core layer, and a through hole 312 being filled with a metallic material. Preferably, the metallic material is composed of Cu or Cu alloy.

Referring to FIG. 4B, combining steps (ii)-(iii) of the present method, the dielectric layers 322 and 324 and the metal layers 332 and 334 are formed by laminating a single-side metal clad 320a or 320b with the dielectric layer 322 or 324 in contact with the existing circuits 310a and 310b, respectively.

Noted that since the through hole 312 has been filled with a metallic material, the single-side metal clad 320a and 320b may be the same or different. Generally, the single-side metal clad 320a or 320b has a thickness of about 10 μm to about 50 μm. The metal foil of said single-side metal clad is composed of Cu, Ni, Ti, W, Al, Cr, Co, Ag, Au, Pd, and alloy thereof; and has a thickness ranging from about 3 μm to about 15 μm.

In one embodiment, the single-side metal clads 320a and 320b are the same.

In another embodiment, the metal foil of single-side metal clad comprises Cu or Cu alloy.

Referring to FIG. 4C, according to step (iv) of the present method, the metal layers 332 and 334 are patterned by photoimaging to form the metal masks 342 and 344 on the respective surface.

Referring to FIG. 4D, according to step (v) of the present method, the dielectric layers 322 and 324 are patterned by plasma etching at areas not shielded by the metal masks 342 and 344 to form indent patterns 352 and 354 on the surface of the respective dielectric layers 322 and 324.

Referring to FIG. 4E, according to step (vi) of the present method, the metal masks 342 and 344 are removed by chemical etching or plasma etching to expose the dielectric layers with the indent patterns 352 and 354.

Referring to FIG. 4F, according to step (vii) of the present method, multiple vias, exemplified by 362 and 364, may be formed by laser drilling or plasma etching to expose a portion of the existing conductors underneath, i.e., the existing circuits 310a and 310b.

Referring to FIG. 4G, according to step (viii) of the present method, a conductive metal is deposited to completely fill the respective indent pattern 352 or 354 to form the trace layer 370a or 370b of each side with excess conductive metal. As the conductive material has filled the vias, these conductive vias 376 and 378 serve as connecting channels between the newly formed trace layer 370a (or 370b) and the respective underneath existing circuit 310a (or 310b).

Referring to FIG. 4H, according to step (ix) of the present method, the excess conductive metal of the trace layer 370a or 370b is removed so that the surfaces of the metal traces 372 or 374 and the conductive via 376 or 378 of each side are coplanar with the surface of the respective dielectric layer 322 or 324. The resulting substrate is a 4-layer circuit structure with new circuits, i.e., the trace layers 370a and 370b embedded in the respective dielectric layers 322 and 324.

### Fourth Embodiment

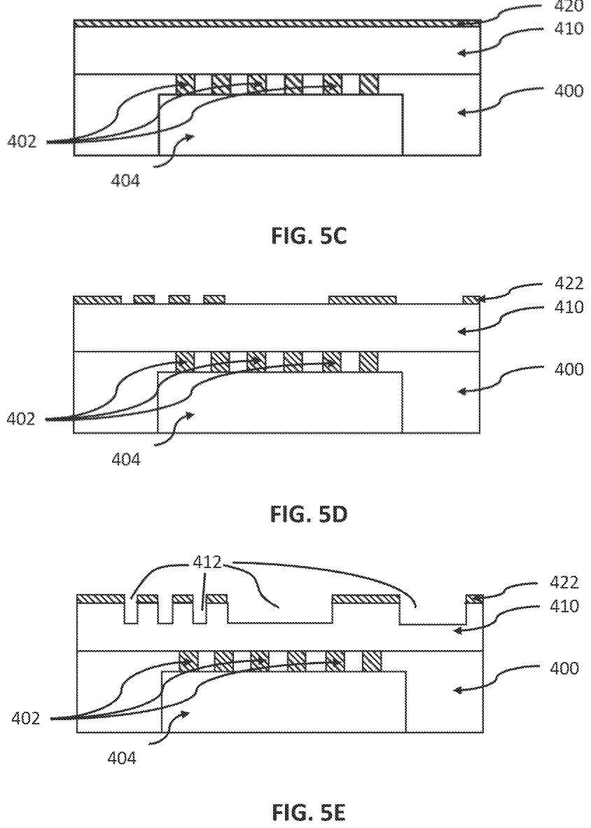

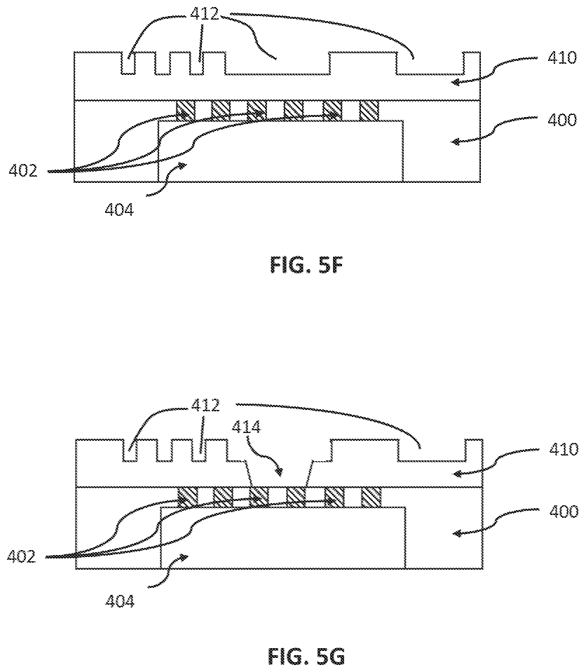

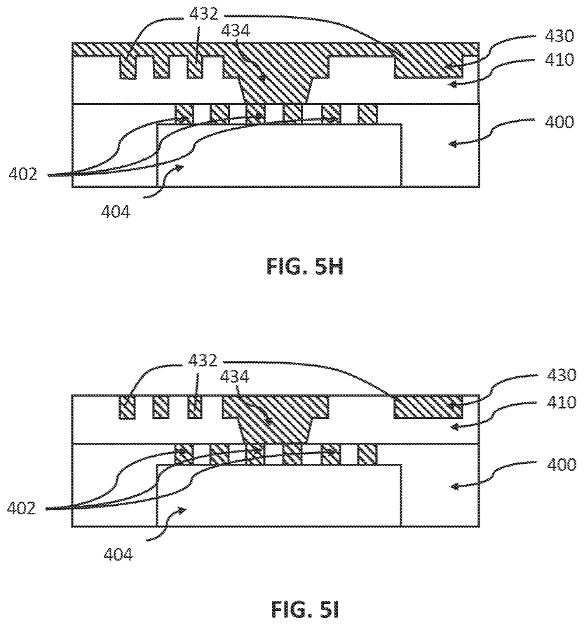

In the fourth embodiment of the present invention, a method for manufacturing a multilayer circuit structure on a package substrate is described. FIGS. 5A-5I are profile flowcharts illustrating the steps according to a fourth embodiment of the present invention. Referring to FIG. 5A, according to step (i) of the present method, a package substrate is provided. The package substrate contains a chip 404 with a plurality of copper pillars 402 is enclosed is a dielectric core layer 400, wherein the top surfaces of the copper pillars 402 are exposed and coplanar with the surface of the dielectric core layer 400. The package substrate generally has a thickness ranging from about 100 μm to about 300 μm.

Referring to FIG. 5B, according to step (ii) of the present method, a dielectric layer 410 is formed on the dielectric core layer 400 by lamination.

Referring to FIG. 5C, according to step (iii) of the present method, a metal layer 420 is deposited on the dielectric layer 410.

Referring to FIG. 5D, according to step (iv) of the present method, the metal layer 420 is patterned by photoimaging to form a metal mask 422. The photoimaging process used to form the metal mask 422 is the same as described in the previous Embodiments.

Referring to FIG. 5E, according to step (v) of the present method, the dielectric layer 410 is patterned by plasma etching at areas not shielded by the metal masks 422 to form indent pattern 412 on the surface of the dielectric layer 410.

Referring to FIG. 5F, according to step (vi) of the present method, the metal mask 422 is removed by chemical etching or plasma etching.

Referring to FIG. 5G, according to step (vii) of the present method, a via 414 is formed by laser drilling to expose a portion of the copper pillars 402 of the chip.

Referring to FIG. 5H, according to step (viii) of the present method, a conductive material is deposited to completely fill the indent pattern and the via to form the trace layer 430 with excess conductive metal to fully cover the dielectric layer 410.

Referring to FIG. 5I, according to step (ix) of the present method, the excess conductive material of the trace layer 430 is removed so that so that the surface of the metal traces 432 and the conductive via 434 are coplanar with the surface of the dielectric layer 410. Therefore, the embedded metal traces and conductive via become the newly formed circuit of the package substrate.

### Fifth Embodiment

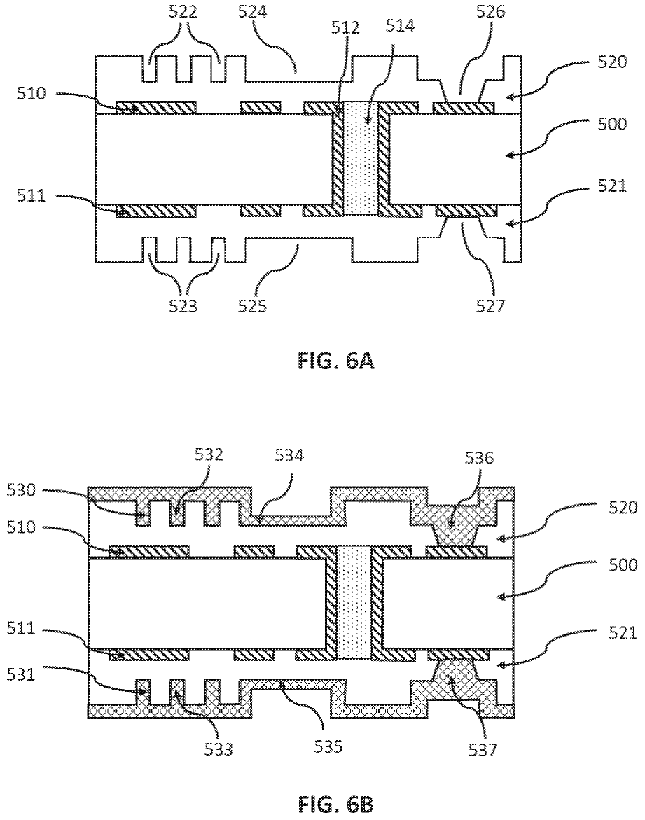

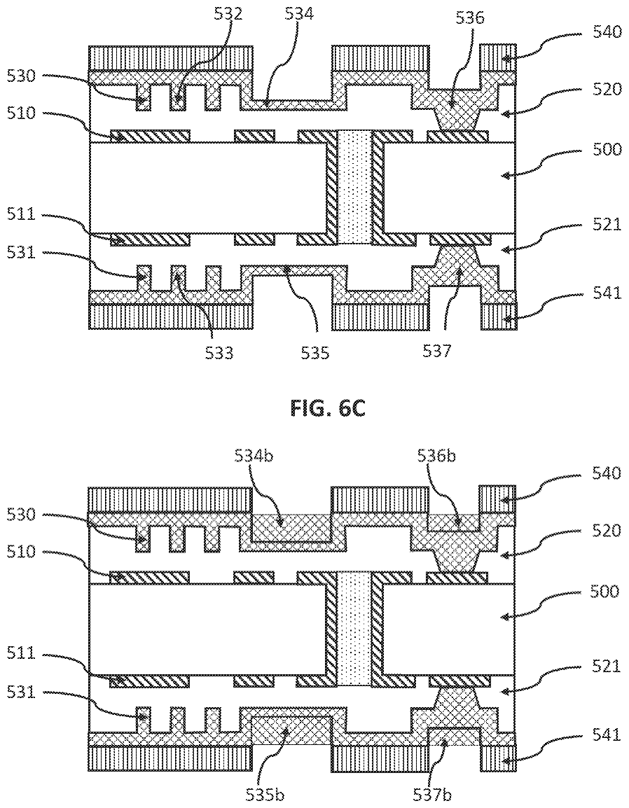

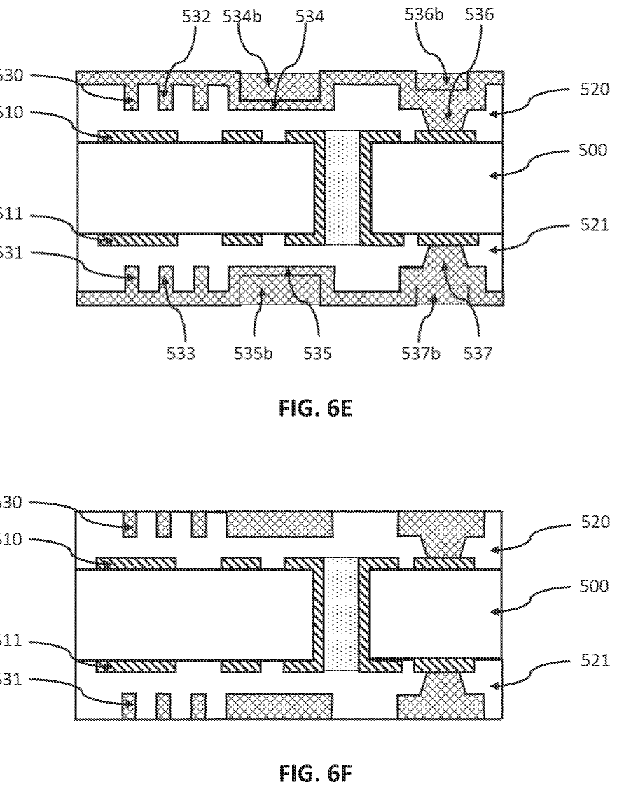

In the fifth embodiment of the present invention, a method for manufacturing a multilayer circuit structure on a double-side PCB is described. FIGS. 6A-6F are profile flowcharts illustrating the steps according to a fifth embodiment of the present method, wherein the step (vii) of depositing a conductive material is performed by a dual electrolytic plating method.

Referring to FIG. 6A, a double-side PCB substrate is provided and subjected to steps (ii)-(vii) of the present method. The substrate after step (vii) contains a dielectric core layer 500, two dielectric layers 520 and 521 on the opposite surfaces of the dielectric core layer 500, two existing circuits 510 and 511 are connected by a through hole having a thin coat of metallic material 512. The core of through hole is filled completely with an organic polymer 514 such as epoxy resin, phenolic resin, or the like.

The dielectric layers 520 and 521 have indent patterns embedded therein. Each indent pattern includes multiple narrow trenches (522 or 523, i.e., trenches have a width no more than 150 μm), wide trenches (524 or 525, i.e., trenches have a width greater than 150 μm), and vias (526 or 527, with a diameter ranging from about 20 μm to about 250 μm).

Referring to FIG. 6B, according to step (viii) of the present method, a conductive metal is deposited by the first time of electroplating to form the respective trace layers 530 and 531. As shown, the narrow trenches are filled with excess conductive metal (i.e., the metal traces 523 and 533), whereas the wide trenches and vias are partially filled to about 50% to 90% of their depths (i.e., the metal traces 534 and 535 as well as the conductive vias 536 and 537).

Referring to FIG. 6C, after the first electrolytic plating, the substrate is subjected to a lithography process to form the patterned resist layers 540 and 541, wherein the narrower metal traces 532 and 533 are masked, and the partial-filled metal traces (534 and 535) and conductive vias (536 and 537) are exposed.

Referring to FIG. 6D, the same conductive metal is deposited by a second electrolytic plating to completely fill the partial-filled metal traces (534 and 535) and conductive vias (536 and 537) in areas marked as 534b, 535b, 536b, and 537b.

Referring to FIG. 6E, the patterned resist layers 540 and 541 are removed to expose the trace layers 530 and 531 with all trenches and vias that are filled with the conductive metal.

Referring to FIG. 6F, the excess portion of each trace layer is removed by planarization method mentioned previously. The resulting substrate is a 4-layer circuit structure with new circuits, i.e., the trace layers 530 and 531 embedded in the respective dielectric layers 520 and 521.

In the following example for manufacturing the multilayer circuit structure according to present method are described in detail.

### Example 1

Step 1. Forming a Dielectric Layer

A single-side PCB (a coupon size: 50 mm×150 mm) was used as the substrate. Said substrate had an existing circuit with traces and pads (about 12 μm in thickness). A dielectric film (manufactured by Ajinomoto Build Film, model GX-92R, 60 μm in thickness) was laminated on the substrate under vacuumed, at 90° C. with a pressure of 0.7 MPa for 60 sec, and then flatten at 90° C. with a pressure of 1.0 MPa for 60 sec.

Step 2. Forming a Metal Layer

A copper layer was deposited on the dielectric layer of the substrate obtained from Step 1, by sputtering copper with a PVD coating machine (manufactured by UVAT Technology Co., model: UHSD-060302T). The fiducial concentration was Copper 4N to form a Cu layer of 0.2 μm in thickness.

Step 3. Forming a Metal Mask

A photoresist layer was formed by laminating a dry film (Riston® TH1015, 15 μm in thickness, manufactured by DuPont Electronics, Inc.) on the copper layer of the substrate obtained from Step 2. A roll laminator was used; the lamination was done at 100° C. with a pressure of 1.4 MPa and a rolling speed of 1.0 meter/minute.

The photoresist pattern was created by using ADTEC IP-8 with a wavelength of 405 nm, by SST=18/41. The test pattern with a conventional design by the PCB fabricator was used, which included line/space set at 20 μM/20 μm, wider trenches up to 60 μm, pads of 120 μm in diameter, and a ground area>2000 μm. After completion of the exposure, development was done by treatment of a 2% Na₂CO₃ solution for 3 minutes so that the uncured part of the photoresist layer was stripped and removed, rinsed with DI water, and dried.

The copper at the unmasked areas were etched away by using a conventional horizontal transporting etching equipment at a speed of 1 m/min and an etchant of a sodium persulfate (Na₂S₂O₈) solution (130 g/L) until completion, rinsed with DI water, and dried.

The photoresist pattern was then stripped and removed by treatment of a 10% NaOH solution for 90 seconds. After rinsing and drying, a copper mask was formed on the substrate.

Step 4. Patterning the Dielectric Layer

After forming the copper mask, the dielectric layer in the exposed areas of the copper mask were etched by plasma etching, using an inductively coupled plasma reactive ion etching (ICP-RIE) system (manufactured by Schmid Group), and the process gas was a mixture of CF₄, O₂, and N₂ for reacting 20 min to form an indent pattern on the dielectric layer with an etching depth of 15 μm.

Step 5. Removing Metal Mask Removal

The copper mask was removed, using a conventional horizontal transporting etching equipment at a speed of 1 m/min and an etchant of a sodium persulfate solution (130 g/L) until completion, rinsed with DI water, and dried.

Step 6. Via Formation

In order to make circuit connection between the existing conductor and the new circuit to be made in subsequent steps, about 250 vias with a diameter of 75 μm were made by laser drilling at the pads to reach the pads of the existing circuit underneath, using a Mitsubishi Laser Drill, model: GTW5, with a CO₂ laser.

Step 7. Depositing Conductive Metal

A seed layer was formed by sputtering Ti, then Cu, using a PVD coating machine (manufactured by UVAT Technology Co., model: UHSD-060302T). The fiducial concentrations were titanium 2N7 and copper 4N. The resulting Ti layer had a thickness 0.1 μm and the Cu layer had a thickness of 0.2 μm.

After forming the seed layer, the first electroplating was conducted in a 20 L paddle plater, with a copper plating additive (MICROFILL™ AET-1, available from DuPont Electronics, Inc.) added in the mother liquor, and a current density of 2.0 ASD for 31 minutes to obtain a plating thickness of about 12 μm at the ground area. The fine lines of the indent pattern, i.e., those trenches have a width of 20 μm to 150 μm were filled completely.

A resist layer was formed on the substrate after the first electroplating by laminating a dry film (Riston® TH1015, 15 μm in thickness). A roll laminator was used; the lamination was done at 100° C. with a pressure of 1.4 MPa and a rolling speed of 1.0 meter/minute.

The resist pattern was created by using ADTEC IP-8 with a wavelength of 405 nm, by SST=18/41. A pattern that would cover the copper-filled fine lines was used. After completion of the exposure, the uncured part of the resist layer was removed by treatment of a 2% Na₂CO₃ solution for 3 minutes, rinsed with DI water, and dried.

After forming the resist pattern, the second electroplating was conducted in a 20 L paddle plater, with a copper plating additive (DuPont MICROFILL™ AET-1) added in the mother liquor, and a current density of 2.0 ASD for 20 minutes to obtain a plating thickness of about 8 μm at the ground area. All the trenches/vias/ground areas of the indent pattern of the dielectric layer was now filled with copper.

The resist pattern was then removed by treatment of a 10% NaOH solution for 90 seconds. After rinsing and drying, a trace layer with excess copper was formed on the substrate.

Step 8. Planarization

The substrate after dual plating process was planarized by a chemical mechanical polishing (CMP) with a polishing pad (manufactured by DuPont, Suba™ 600) and a slurry (RDS MK10-001). The operation parameters were as follows: a pad/holder speed of 223/211, a down force of 3 psi, process time of 120 seconds, and a slurry flow rate of 80 mL/min.

After rising and drying, the substrate with a new embedded circuit was obtained, i.e., an embodiment of the present multilayer circuit structure. The multilayer circuit structure manufactured by the present method was then evaluated with a cross-section analysis with a microscope.

While the invention has been illustrated and described in typical embodiments, it is not intended to be limited to the details shown, since various modifications and substitutions are possible without departing from the spirit of the present invention. As such, modifications and equivalents of the invention herein disclosed may occur to persons skilled in the art using no more than routine experimentation, and all such modifications and equivalents are believed to be within the spirit and scope of the invention as defined by the following claims.

What is claimed is:

1. A method for manufacturing a multilayer circuit structure, comprising:
(i) providing a substrate having at least one layer of an existing conductor, where the substrate is a single-side printed circuit board, a double-side printed circuit board, or a package substrate;
(ii) forming a dielectric layer covering the existing conductor;
(iii) forming a metal layer on the dielectric layer;
(iv) patterning the metal layer by photoimaging to form a metal mask;
(v) plasma etching the dielectric layer to form an indent pattern composed of multiple trenches and pads on the surface of the dielectric layer at areas not shielded by the metal mask;
(vi) optionally, removing the metal mask by chemical etching or plasma etching;
(vii) forming at least one via at a pad by laser drilling or plasma etching to expose a portion of the existing conductors underneath;
(viii) depositing a conductive metal completely filling the patterned dielectric layer to form an embedded trace layer with excess conductive metal; and
(ix) planarizing to remove the excess conductive metal of step (viii) to form a new circuit embedded in the dielectric layer of the substrate;
wherein
when the substrate is a double-side printed circuit board, then steps (ii)-(ix) are applicable to the existing conductors located on both side of the substrate, the double-side printed circuit board has at least one through hole, and the through hole is filled with a metallic material composed of Cu or Cu alloy or an organic polymer composed of epoxy resin or phenolic resin.

2. The method of claim 1, wherein the step (iv) patterning the metal layer by photoimaging, comprises:
(a) coating or laminating a layer of photoresist on the metal layer,
(b) patterning the photoresist,
(c) etching the metal layer in the exposed areas by plasma etching or chemical etching; and
(d) removing the remained photoresist pattern by stripping or etching to obtain a metal mask.

3. The method of claim 1, wherein the substrate is a single-side print circuit board or a double-side print circuit board, that the substrate has a thickness ranging from about 40 μm to about 800 μm, and is derived from a copper clad laminate that has a base sheet composed of a reinforced resin or a resin coated copper foil, and the resin is selected from epoxy resin, phenolic resin, bismaleimide-triazine resin, polyimide, cyanate ester resin, polyphenylene oxide, liquid crystal polymer, polytetrafluoroethylene, and mixtures thereof.

4. The method of claim 1, wherein the substrate is a package substrate, that is loaded with at least one chip and has a plurality of exposed copper pillars, and the package substrate has a thickness ranging from about 100 μm to about 300 μm.

5. The method of claim 1, wherein the dielectric layer of step (ii) has a thickness ranging from about 10 μm to about 80 μm.

6. The method of claim 1, wherein the dielectric layer of step (ii) comprises a thermally curable polymer selected from epoxy resin, bismaleimide-triazine resin, polyimide, cyanate ester resin, polyphenylene oxide, liquid crystal polymer, polytetrafluoroethylene, and mixtures thereof.

7. The method of claim 6, wherein the dielectric layer of step (ii) further comprises a reinforcing material or a plurality of fillers, where the reinforcing material is in form of fibers or a fabric, and comprises E-glass, S-glass, quartz, ceramic, or aramid; the fillers are particles comprising silicon oxide, aluminum oxide, boron nitride, or mixtures thereof; and the filler particles have an average diameter ranging from about 1 μm to about 20 μm.

8. The method of claim 1, wherein the metal layer of step (iii) is formed by physical vapor deposition, chemical vapor deposition, or electroless-plating.

9. The method of claim 1, wherein the metal layer of step (iii) is composed of Cu, Ni, Ti, W, Al, Cr, Co, Ag, Au, Pd, and alloy thereof; and has a thickness ranging from about 0.1 μm to about 15 μm.

10. The method of claim 1, wherein the conductive metal of step (viii) is deposited by electrolytic plating.

11. The method of claim 1, wherein the conductive metal of step (viii) is deposited by pre-forming a seed layer by physical vapor deposition, chemical vapor deposition, or electroless plating; and followed by electrolytic plating.

12. The method of claim 10 or claim 11, wherein the electrolytic plating includes a single plating method or a dual plating method.

13. The method of claim 12, wherein the dual plating method comprises:
I. forming a patterned resist layer to mask the trenches and vias having a trench width and a via diameter of 150 μm or less;
II. electrolytic plating the first time to deposit conductive metal to the unmasked trenches and vias having a trench width and a via diameter greater than 150 μm to fill up to about 50-90% of the depth of the trenches and vias;
III. removing the patterned resist layer to expose the trenches and vias having a trench width and a via diameter of 150 μm or less; and
IV. electrolytic plating the second time to ensure all the trenches and vias has been 100% filled with the conductive metal.

14. The method of claim 12, wherein the dual plating method comprises:
A. electrolytic plating the first time to deposit conductive metal to completely fill the depth of each trench and via having a trench width and a via diameter of 150 μm or less;
B. forming a patterned resist layer to mask the trenches and vias having been completely filled with the conductive metal in Step A;
C. electrolytic plating the second time to ensure all the unmasked trenches and vias having a trench width and a via diameter greater than 150 μm to be filled at least to 100% of the depth of the trenches and vias; and
D. removing the patterned resist layer to expose the trenches and vias having completely filled with the conductive metal in Step A.

15. The method of claim 1, wherein the new circuit, excluding the conductive vias, has an embedded depth ranging from about 5 μm to about 50 μm.

16. The method of claim 1, wherein the new circuit consists a plurality of metal traces and conductive vias, each metal trace has a width ranging from about 5 μm to about 2500 μm, and each conductive via has a diameter ranging from about 20 μm to about 250 μm.

17. The method of claim 1, wherein steps (ii)-(ix) is repeated multiple times to obtain a multilayer circuit structure.

18. The method of claim 1, wherein step (ii) and (iii) is combined by laminating a metal clad on the substrate of step (i), where the metal clad is composed of a dielectric layer of step (ii) and a metal layer of step (iii),

19. A multilayer circuit structure manufactured by the method of claim 1, comprising:
a substrate having at least one layer of an existing conductor, where the substrate is a single-side printed circuit board, a double-side printed circuit board, or a package substrate; and
a dielectric layer having an embedded new circuit formed on top of the substrate's existing conductor;
wherein
the substrate is a single-side print circuit board that has a thickness ranging from about 40 μm to about 800 μm;
the substrate is a double-side print circuit board having at least one through hole, the through hole is filled with a metallic material composed of Cu or Cu alloy, or an organic polymer, and the double-side print circuit board has a thickness ranging from about 40 μm to about 800 μm; or
the substrate is a package substrate loaded with at least one chip and a plurality of exposed copper pillars, and the package substrate has a thickness ranging from about 100 μm to about 300 μm;
the dielectric layer has a thickness ranging from about 10 μm to about 80 μm;
the new circuit consists a plurality of metal traces and conductive vias, where each metal trace has a width ranging from about 5 μm to about 2500 mm and an embedded depth ranging from about 5 μm to about 50 μm, and each conductive via has a diameter ranging from about 20 μm to about 250 μm and an embedded depth allowing connection with the existing conductor.
